(19) United States
(12) Patent Application Publication
(10) Pub. No.: US 2017/0062412 A1
(43) Pub. Date: Mar. 2, 2017

(54) TRANSISTOR ELEMENT AND SEMICONDUCTOR DEVICE

(71) Applicant: Mitsubishi Electric Corporation, Tokyo (JP)

(72) Inventors: Makoto KAWANO, Fukuoka (JP); Kazutoyo TAKANO, Fukuoka (JP); Yukitaka HORI, Fukuoka (JP)

(73) Assignee: Mitsubishi Electric Corporation, Tokyo (JP)

(21) Appl. No.: 15/132,273

(22) Filed: Apr. 19, 2016

(30) Foreign Application Priority Data
Aug. 25, 2015 (JP) 2015-165964

(51) Int. Cl. H01L 27/06; H01L 21/265; H01L 23/522; H01L 29/49; H01L 29/739; H01L 29/16

(52) U.S. Cl. CPC H01L 27/0629; H01L 29/7393; H01L 29/1608; H01L 27/0635; H01L 23/5228; H01L 29/4916; H01L 21/265

(57) ABSTRACT

A transistor element includes: a first semiconductor substrate on which a first transistor cell region is formed; a first gate electrode pad formed on the first semiconductor substrate and connected to a gate in the first transistor cell region; a relay electrode pad formed on the first semiconductor substrate; and a gate resistance formed on the first semiconductor substrate and connected between the first gate electrode pad and the relay electrode pad.

### BACKGROUND OF THE INVENTION

Field

The present invention relates to a transistor element and a semiconductor device.

Background

MOS transistors and IGBTs having an insulated-gate-type structure are widely being used as switching transistor elements (see, for example, Japanese Patent Laid-Open No. 2000-179440). For example, with respect to one switching circuit configuration, uses of such transistor elements include, as well as a simple use of one single transistor element, a use of transistor elements of different characteristics (types) connected in parallel with each other so that their characteristics complement each other in order to obtain improved characteristics.

In a case where transistor elements of different characteristics (types) having an insulated-gate-type structure (e.g., SJMOS/SiC-MOS and Si-IGBT elements) are connected in parallel with each other, gate resistances are connected for the purpose of adjusting the switching characteristics of each transistor element. The gate resistances may be external resistances externally connected to the transistor elements (chips) (see, for example, Japanese Patent Laid-Open No. 2000-179440). However, the cost and space for providing the gate resistances can be reduced if the gate resistances are incorporated in the transistor elements, thereby making external resistances unnecessary.

In a case where the gate resistance values are changed in a conventional semiconductor device having gate resistances respectively incorporated in transistor elements, however, there is a need to newly develop transistor elements for all of those connected in parallel with each other.

### SUMMARY

In view of the above-described problem, an object of the present invention is to provide a transistor element and a semiconductor device capable of reducing the manufacturing cost for the semiconductor device by shortening the development time.

According to the present invention, a transistor element includes: a first semiconductor substrate on which a first transistor cell region is formed; a first gate electrode pad formed on the first semiconductor substrate and connected to a gate in the first transistor cell region; a relay electrode pad formed on the first semiconductor substrate; and a gate resistance formed on the first semiconductor substrate and connected between the first gate electrode pad and the relay electrode pad.

In the present invention, the transistor element incorporates the gate resistance for the other transistor element connected in parallel with the transistor element. Therefore, a conventional transistor element can be used as the other transistor element, thus reducing the number of chip alteration points accompanying a change of the gate resistance. Consequently, the development time for the semiconductor device can be shortened and the manufacturing cost can be reduced.

Other and further objects, features and advantages of the invention will appear more fully from the following description.

### BRIEF DESCRIPTION OF DRAWINGS

FIG. 1 is a diagram schematically showing a semiconductor device according to a first embodiment of the present invention.

FIG. 2 is a diagram schematically showing a concrete example of the first transistor element according to the first embodiment of the present invention.

FIG. 3 is a diagram schematically showing a semiconductor device according to the comparative example.

FIG. 4 is a sectional view of the first transistor element according to a second embodiment of the present invention.

FIGS. 5 to 7 are sectional views of the first transistor element according to a third embodiment of the present invention.

FIGS. 8 and 9 are sectional views of the first transistor element according to a fourth embodiment of the present invention.

FIG. 10 is a diagram schematically showing the first transistor element according to a fifth embodiment of the present invention.

FIG. 11 is a diagram schematically showing the first transistor element according to a sixth embodiment of the present invention.

FIG. 12 is a sectional view of the first transistor element according to a seventh embodiment of the present invention.

FIGS. 13 and 14 are diagrams schematically showing a semiconductor device according to an eighth embodiment of the present invention.

FIG. 15 is a diagram schematically showing a concrete example of the first transistor element according to a ninth embodiment of the present invention.

FIG. 16 is a sectional view of the first transistor element according to a tenth embodiment of the present invention.

FIG. 17 is a diagram schematically showing the first transistor element according to the tenth embodiment of the present invention.

FIG. 18 is a sectional view of the first transistor element according to an eleventh embodiment of the present invention.

FIG. 19 is a diagram schematically showing the first transistor element according to the eleventh embodiment of the present invention.

### DESCRIPTION OF EMBODIMENTS

A transistor element and a semiconductor device according to the embodiments of the present invention will be described with reference to the drawings. The same components will be denoted by the same symbols, and the repeated description thereof may be omitted.

### First Embodiment

FIG. 1 is a diagram schematically showing a semiconductor device according to a first embodiment of the present invention. The semiconductor device 100 has a first transistor element 1 and a second transistor element 4 connected in parallel with each other and a gate driver element (IC) 7. These elements are chips separate from each other. The first transistor element 1 has a first semiconductor substrate 2 on which a first transistor cell region is formed. The transistor cell region is a region other from a terminal region and a gate wiring portion and defined basically to have a plurality of transistor cells disposed therein. A first gate electrode pad G1 is formed on the first semiconductor substrate 2 and is electrically connected to a gate in the first transistor cell region. A first emitter electrode E1 is formed on the first semiconductor substrate 2 and is connected to an emitter in the first transistor cell region.

A gate resistance RG1 is connected between the first gate electrode pad G1 and the gate in the first transistor cell region. The switching speed of the first transistor element 1 itself can be controlled by means of the gate resistance RG1. The switching speed can therefore be reduced by increasing the resistance value to prevent surge breakdown or the like due to high dv/dt or an oscillation phenomenon at the time of switching. The gate resistance RG1 may be 0Ω, that is, the gate resistance RG1 may not be provided.

A relay electrode pad 3 is formed on the first semiconductor substrate 2. A gate resistance RG2 is formed on the first semiconductor substrate 2 and is connected between the first gate electrode pad G1 and the relay electrode pad 3.

The second transistor element 4 has a second semiconductor substrate 5 on which a second transistor cell region is formed. The first transistor element 1 and the second transistor element 4 have an insulated-gate-type structure in common but have characteristics different from each other. A second gate electrode pad G2 is formed on the second semiconductor substrate 5 and is electrically connected to a gate in the second transistor cell region. A second emitter electrode E2 is formed on the second semiconductor substrate 5 and is connected to an emitter in the second transistor cell region. A gate resistance RG0 indicates a piece of wiring which connects the second gate electrode pad G2 and the gate in the second transistor cell region to each other, and represents a state where no second gate resistance is formed in this case (RG0=0Ω). A wire 6 connects the relay electrode pad 3 of the first transistor element 1 and the second gate electrode pad G2 of the second transistor element 4 to each other. The wire 6 is a thin wire made of, for example, gold (Au) or aluminum (Al). Collector electrodes (not shown) are formed on back surfaces of the first and second semiconductor substrates 2 and 5.

A gate signal from the gate driver element 7 is supplied to the first gate electrode pad G1 of the first transistor element 1 through a wire 8. The gate signal is input to the first transistor element 1 and is also input to the second transistor element 4 through the gate resistance RG2 incorporated in the first transistor element 1. Therefore, the gate resistance value, i.e., the switching speed, of the second transistor element 4 can be adjusted by means of the gate resistance RG2 incorporated in the first transistor element 1.

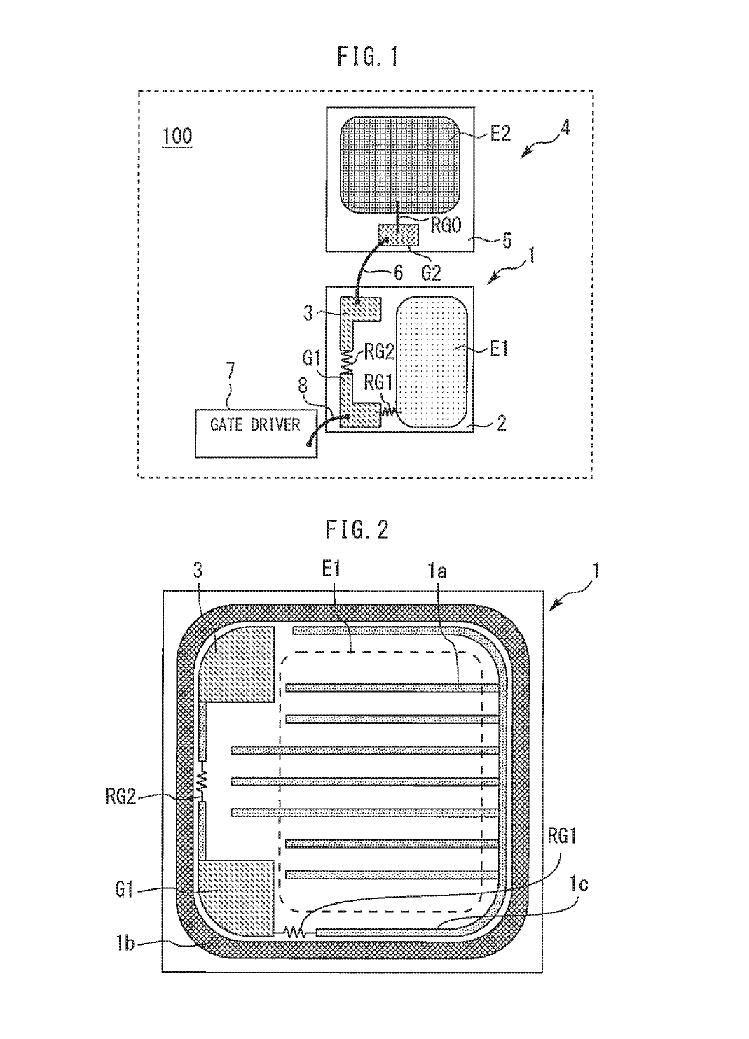

FIG. 2 is a diagram schematically showing a concrete example of the first transistor element according to the first embodiment of the present invention. The first emitter electrode pad E1, which is formed of a metallic material such as AlSi, and which is on the surface of the first transistor element 1, is indicated by a broken line in FIG. 2 for convenience sake. A plurality of trench gates 1a are formed in the first transistor cell region in the first transistor element 1, and a terminal region 1b is formed around the first transistor cell region. The trench gates 1a are connected to the first gate electrode pad G1 via gate wiring 1c. The gate resistance RG1 is formed at an intermediate position in the gate wiring 1c. The gate resistance RG1 therefore functions as an incorporated gate resistance incorporated in the first transistor element 1. The gate resistance RG2 is formed at an intermediate position in the gate wiring connecting the gate electrode pad G1 and the relay electrode pad 3 in the first transistor element 1 and is connected to the second transistor element 4 through the relay electrode pad 3. Therefore, the gate resistance RG2 functions not as a gate resistance for the first transistor element 1 but as a gate resistance for the second transistor element 4. The relay electrode pad 3 is connected to the gate electrode pad G2 of the second transistor element 4 through the wire 6. Each of the gate electrode pad G1 and the relay electrode pad 3 is formed of a metallic material such as AlSi, while each of the gate wiring 1c and the gate resistances RG1 and RG2 is formed of polysilicon. However, the materials of the electrode pads, the gate wiring and the gate resistances are not limited to these.

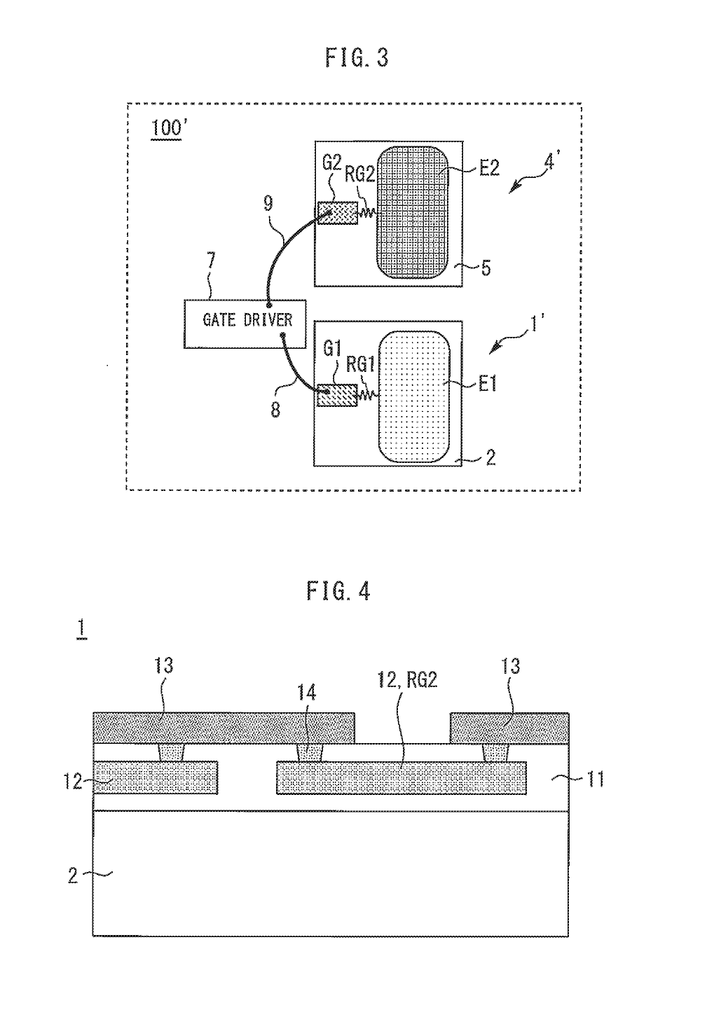

The advantages of the present embodiment will be described in comparison with a comparative example. FIG. 3 is a diagram schematically showing a semiconductor device according to the comparative example. In the semiconductor device 100′ according to the comparative example, transistor elements 1′ and 4′ connected in parallel with each other incorporate the gate resistances RG1 and RG2, respectively. A gate signal from the gate driver element 7 is supplied to the gate electrode pads G1 and G2 of the first and second transistor elements 1′ and 4′ through wires 8 and 9.

On the other hand, in the present embodiment, the first transistor element 1 incorporates the gate resistance RG2 for the second transistor element 4 connected in parallel with the first transistor element 1 as well as the gate resistance RG1 for the first transistor element 1. When a need to change the gate resistances arises accompanying adjustment, alteration or the like of the switching speed, changing only the first transistor element 1 thereby suffices and a conventional transistor element can be used as the second transistor element 4, thus reducing the number of chip alteration points accompanying a change of the gate resistance. Consequently, the development time for the semiconductor device can be shortened and the manufacturing cost can be reduced. In particular, the gate resistance RG2 used for the high-priced second transistor element 4 is incorporated in the low-priced first transistor element 1, thereby eliminating the need for changing the high-priced second transistor element 4 while avoiding increasing causes of defects accompanying process addition. The manufacturing cost can thus be reduced.

The second transistor element 4 differs in characteristics (in withstand voltage class) from the first transistor element 1. A bipolar element such as an IGBT can be destroyed when breaking down, depending on the structure. Therefore, a unipolar element which can be avalanche-proof and a bipolar element having a withstand voltage higher than that of the unipolar element may be combined to prevent element destruction caused by overvoltage breakdown. More specifically, a MOSFET which can be avalanche-proof and an IGBT of a withstand voltage class higher than that of the MOSFET may be combined, so that the MOSFET first breaks down to prevent overvoltage breakdown of the IGBT.

For example, in a case where an Si-IGBT and an SiC-MOSFET of the same rated current are connected in parallel with each other as the first and second transistor elements 1 and 4, there is a problem that if no gate resistance is provided, the entire current is concentrated on the SiC-MOSFET side at the time of switching, because the SiC-MOSFET is higher in speed than the Si-IGBT both on the side and on the off side. Avoiding this problem requires connecting a gate resistance to the SiC-MOSFET such that the switching speed of the MOSFET is reduced and the partial current loads on the Si-IGBT and the SiC-MOSFET during the switching transition period are optimized, thereby preventing element destruction caused by current concentration on the SiC-MOSFET.

In the conventional art, a gate resistance is incorporated in each of the Si-IGBT and SiC-MOSFET elements (chips). However, the chip unit price of the SiC-MOSFET is high. The manufacturing cost can be reduced by incorporating in the Si-IGBT a gate resistance used for the Si-MOSFET as in the present embodiment.

### Second Embodiment

FIG. 4 is a sectional view of the first transistor element according to a second embodiment of the present invention. A multilayer oxide film 11 is provided on the first semiconductor substrate 2, which is an Si substrate. Polysilicon 12 for forming the gate resistance RG2 is provided in the oxide film 11 by introducing (adding) an impurity. Al electrodes 13 are provided on the oxide film 11. The polysilicon 12 and the Al electrodes 13 are connected to each other via contact holes 14.

The polysilicon 12 for forming the gate resistance RG2 is formed by ion implanting an impurity in non-doped polysilicon, as is the incorporated gate resistance in the conventional art. The gate resistance value can easily be adjusted by the amount of implantation of the impurity in the non-doped polysilicon.

### Third Embodiment

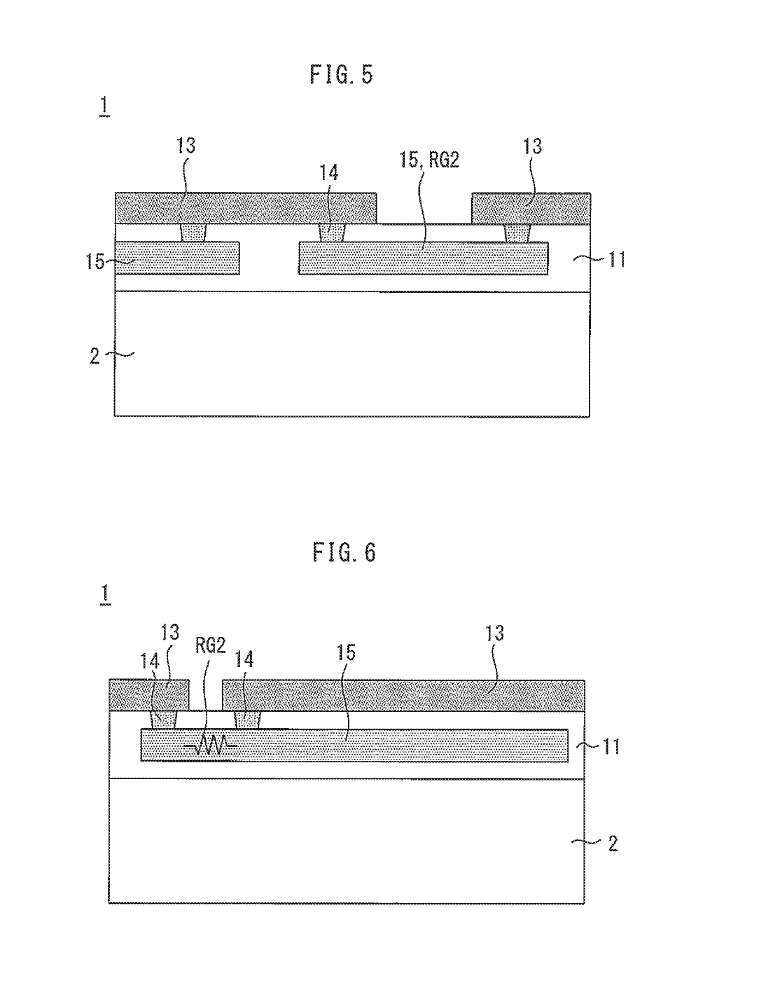

FIGS. 5 to 7 are sectional views of the first transistor element according to a third embodiment of the present invention. While the polysilicon 12 in the second embodiment is formed by ion implanting an impurity in non-doped polysilicon, doped polysilicon is used in the present embodiment.

Polysilicon 15 for forming the gate resistance RG2 is formed by using doped polysilicon, as are the existing internal resistances. That is, the polysilicon 15 is doped with an impurity at the time of deposition to make (set) the resistance value with, for example, a mask for contact holes to the gate wiring or Al wiring. The sequence of process steps (photoengraving processing, ion implantation) for forming the gate resistance RG2 from the non-doped polysilicon can thereby be omitted. In some cases, the diffusion step can also be omitted.

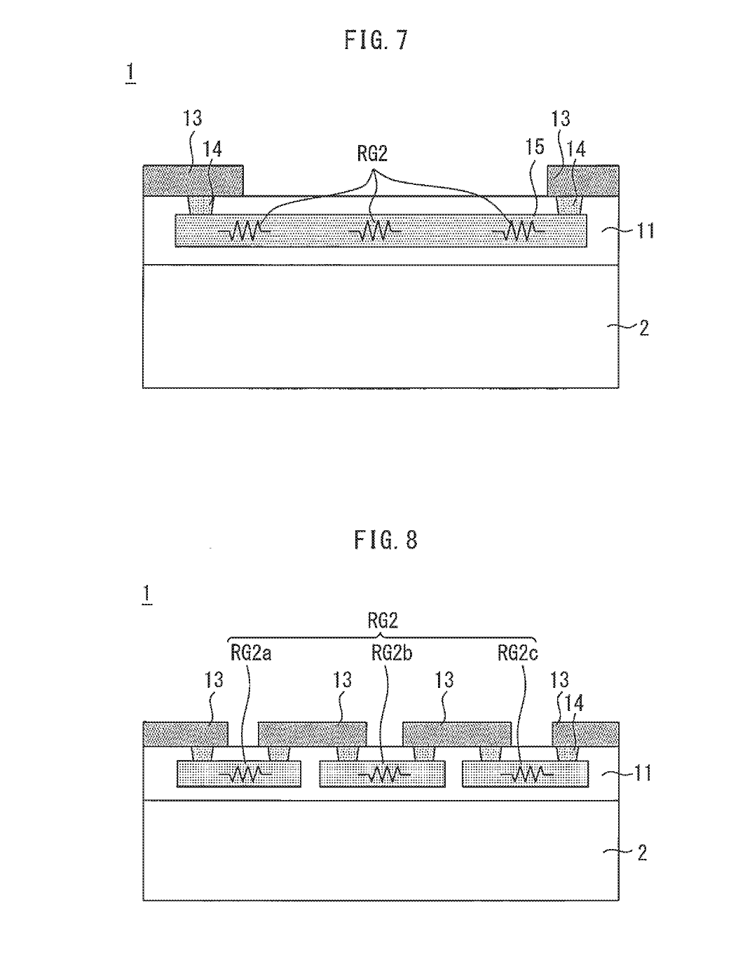

The resistance value of the gate resistance RG2 can be adjusted by means of the design size of the mask for the polysilicon 15. The gate resistance value may be adjusted alternatively by changing the positions of contacts between Al electrodes 13 on the surface and the polysilicon 15, i.e., the distance between the contacts, for example, from the position shown in FIG. 6 to the position shown in FIG. 7. These methods of adjusting the resistance value can also be applied to the second embodiment. In the case of use of this method in the second embodiment, however, there is a need to alter the mask for forming the Al electrodes 13 and the mask for forming the contact holes 14.

### Fourth Embodiment

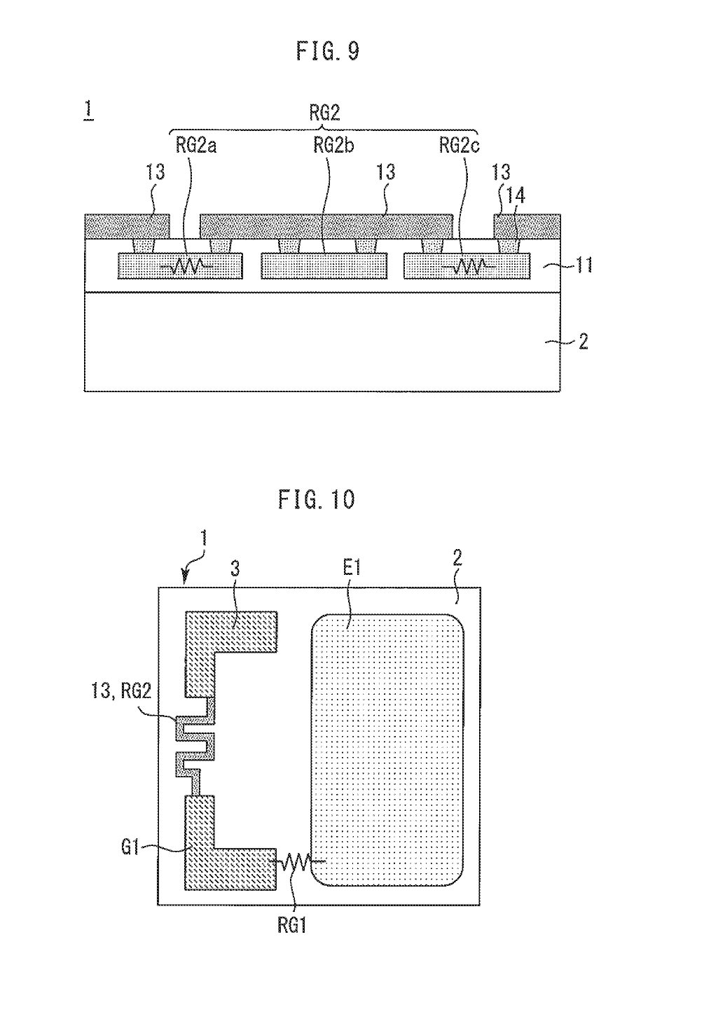

FIGS. 8 and 9 are sectional views of the first transistor element according to a fourth embodiment of the present invention. The gate resistance RG2 has a plurality of resistances RG2a, RG2b, and RG2c separate from each other and made of polysilicon, Al electrodes 13 which connect the plurality of resistances RG2a, RG2b, and RG2c to one another, and contact holes 14. The polysilicon for each of the plurality of resistances RG2a, RG2b, and RG2c is the non-doped polysilicon doped with an impurity according to the second embodiment or the doped polysilicon according to the third embodiment.

As can be understood from comparison between FIGS. 8 and 9, the gate resistance value can be adjusted by means of the positions of contact of the Al electrodes 13 on the surface with the plurality of resistances RG2a, RG2b, and RG2c. In this case, the resistance value in the arrangement shown in FIG. 9 is smaller than that in the arrangement shown in FIG. 8. The resistance value can easily be changed only by altering the masks for the Al electrodes 13 and other portions formed after the Al electrodes 13. Also, the number of masks to be altered at the time of resistance value adjustment can be reduced. As a result, the mask preparation time can be shortened and the manufacturing cost can be reduced.

### Fifth Embodiment

FIG. 10 is a diagram schematically showing the first transistor element according to a fifth embodiment of the present invention. The gate resistance RG2 is formed by using Al electrodes 13 provided on the chip surface. The sequence of process steps (photoengraving processing, ion implantation, diffusion) for forming a resistance by using polysilicon can thereby be omitted. The gate resistance value can be adjusted by means of the mask design size for the Al electrodes 13.

### Sixth Embodiment

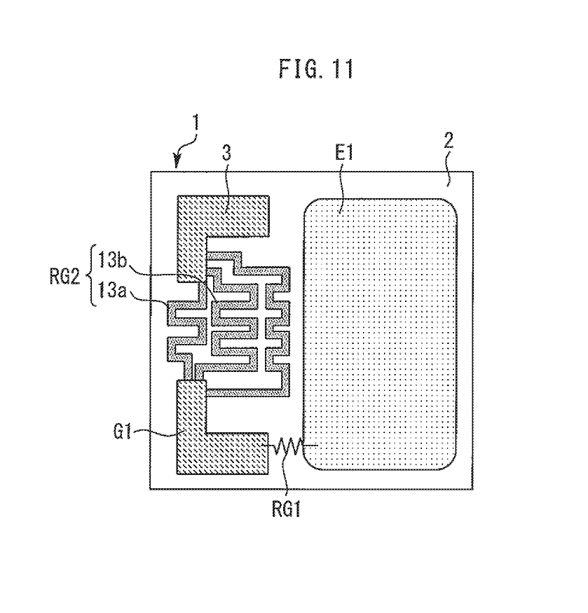

FIG. 11 is a diagram schematically showing the first transistor element according to a sixth embodiment of the present invention. The gate resistance RG2 has a plurality of Al electrodes 13a, 13b connected in parallel with each other. Even after the completion of the wafer process, the gate resistance value can be adjusted by cutting one of the Al electrodes 13a, 13b with a tool externally applied.

### Seventh Embodiment

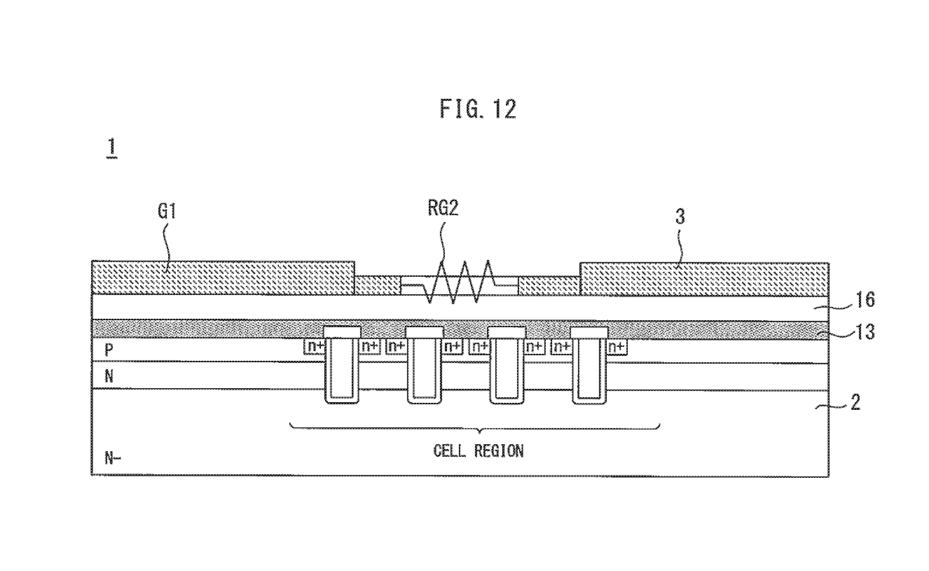

FIG. 12 is a sectional view of the first transistor element according to a seventh embodiment of the present invention. An insulating film 16 is formed on Al electrodes 13 in the first transistor cell region of the first transistor element 1. The relay electrode pad 3 made of Al and the gate resistance RG2 are disposed on the insulating film 16. A reduction in effective area can be avoided by providing the Al electrodes on the surface in a two-layer structure and disposing the relay electrode pad 3 and the gate resistance RG2 on the cell region as described above.

### Eighth Embodiment

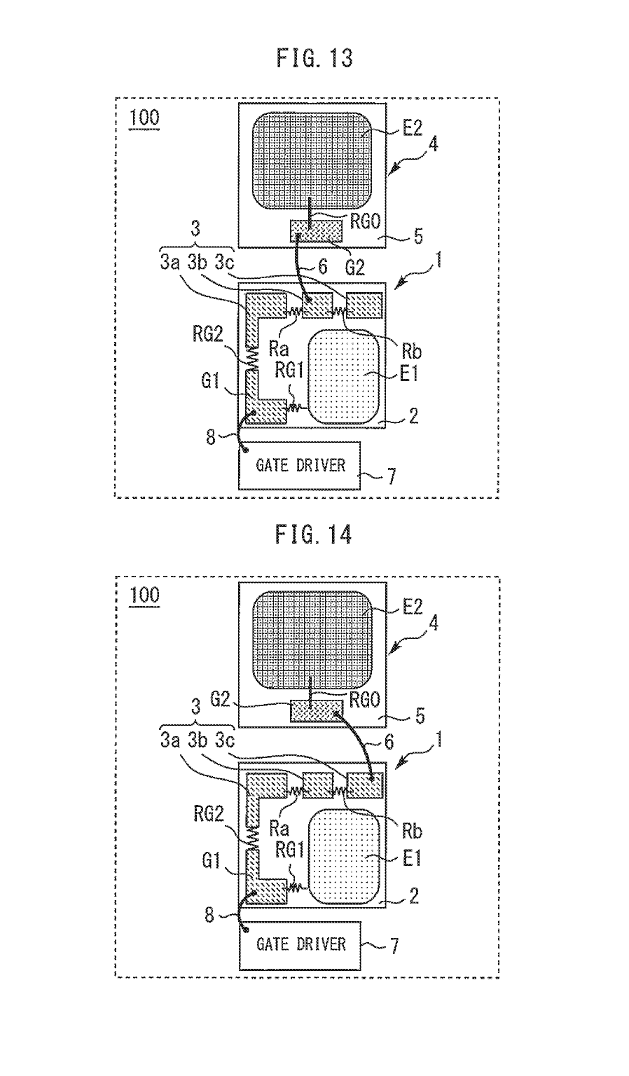

FIGS. 13 and 14 are diagrams schematically showing a semiconductor device according to an eighth embodiment of the present invention. A group of relay electrode pads 3 including a plurality of electrode pads 3a, 3b, and 3c connected in series with each other are provided and resistances Ra and Rb are connected between the plurality of electrode pads 3a, 3b, and 3c, respectively. As can be understood from comparison between FIGS. 13 and 14, the gate resistance value can easily be changed by changing the connection of the wire 6 to one of the plurality of electrode pads 3a, 3b, and 3c. As a result, the mask preparation time can be shortened and the manufacturing cost can be reduced.

### Ninth Embodiment

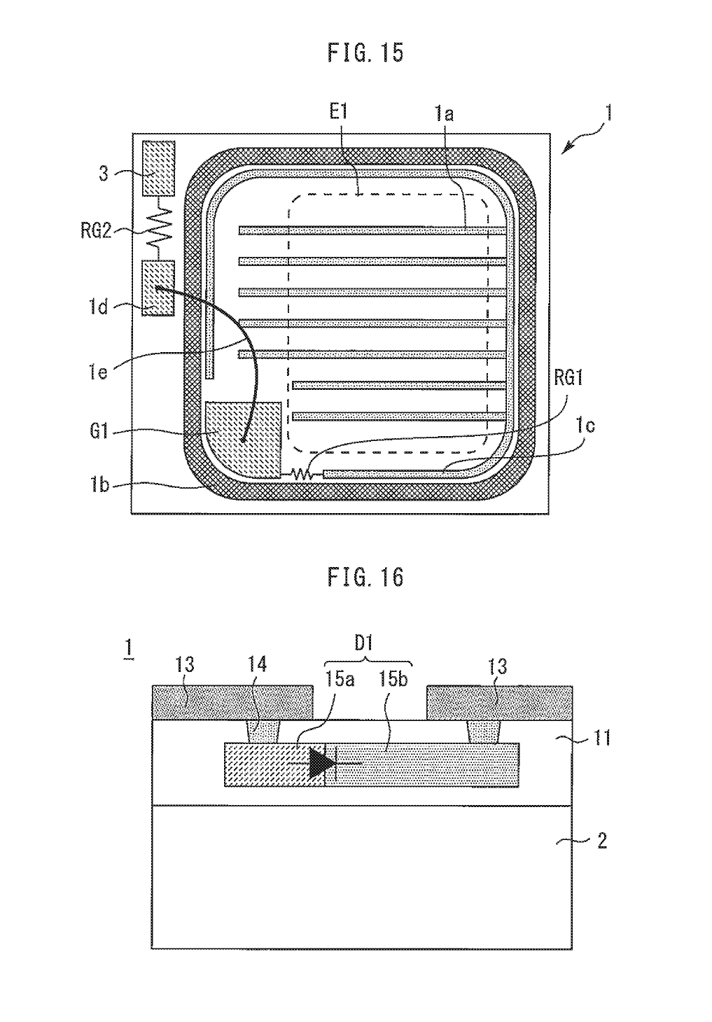

FIG. 15 is a diagram schematically showing a concrete example of the first transistor element according to a ninth embodiment of the present invention. The relay electrode pad 3 and the gate resistance RG2 connected to the gate electrode pad G2 of the second transistor element 4 are disposed in a region other than the transistor cell region of the first transistor element 1. A relay terminal 1d connected to the gate resistance RG2 is connected to the gate electrode pad G1 of the first transistor element 1 by a wire 1e. A reduction in effective area of the transistor cell region caused by forming of the relay electrode pad 3 and the gate resistance RG2 can thus be avoided.

### Tenth Embodiment

FIG. 16 is a sectional view of the first transistor element according to a tenth embodiment of the present invention. A diode D1 is formed on the first semiconductor substrate 2. The diode D1 is formed of p-type doped polysilicon 15a and n-type doped polysilicon 15b. The diode D1 is connected between the first gate electrode pad G1 and the relay electrode pad 3, thereby enabling adjustment of the gate voltage applied to the second transistor element 4.

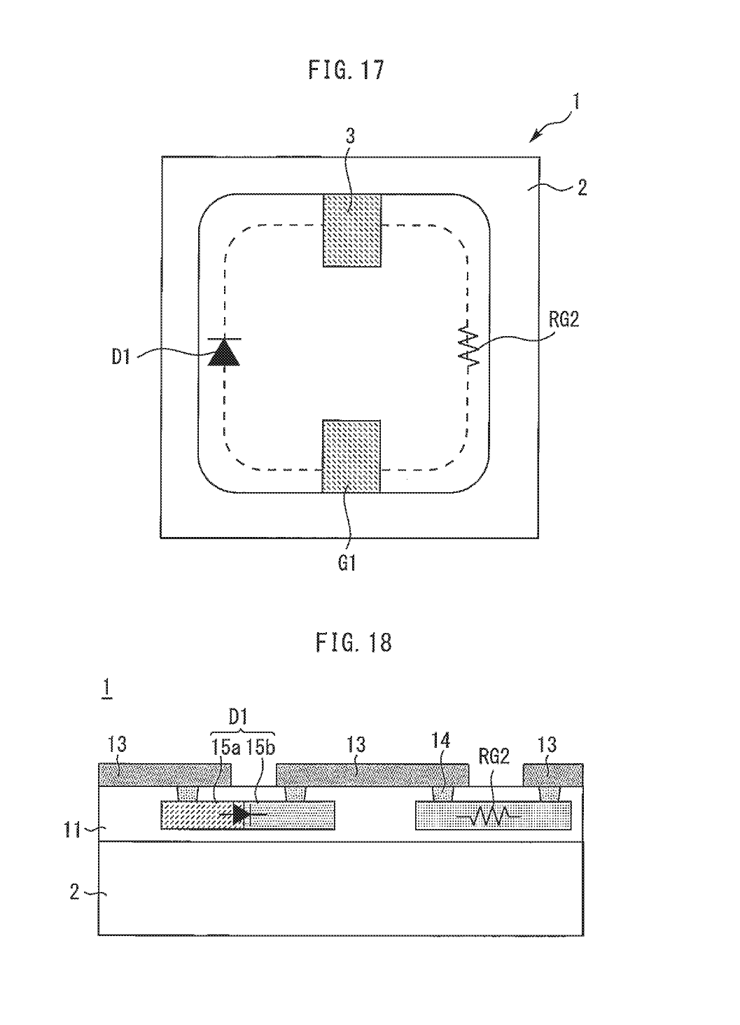

FIG. 17 is a diagram schematically showing the first transistor element according to the tenth embodiment of the present invention. The diode D1 is connected in parallel with the gate resistance RG2, thus enabling use of the diode D1 for control when the transistor element is off.

### Eleventh Embodiment

FIG. 18 is a sectional view of the first transistor element according to an eleventh embodiment of the present invention. The diode D1 is connected in series with the gate resistance RG2. Thereby, when transistor elements differing in gate withstand capacity are connected in parallel with each other, the connection to the second transistor elements 4 lower in gate withstand capacity is made through the diode D1 to reduce the voltage applied to the gate, thus enabling relieving the gate stress.

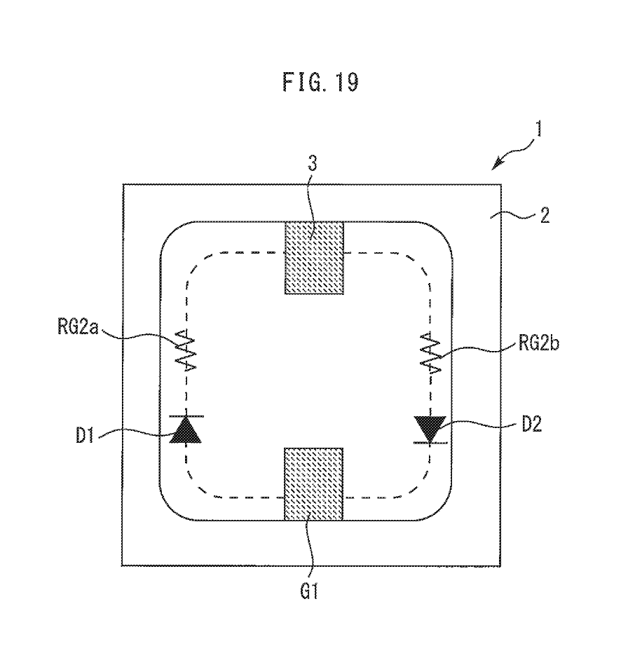

FIG. 19 is a diagram schematically showing the first transistor element according to the eleventh embodiment of the present invention. The gate resistance RG2 include first and second gate resistances RG2a and RG2b connected in parallel with each other. Diodes D1 and D2 are in a reverse parallel connection with each other and are connected in series with the first and second gate resistances RG2a and RG2b, respectively. With this arrangement, the gate resistance values during on-off operations of the second transistor element 4 can be individually adjusted to adjust the partial current loads during the switching transition period.

While the above-mentioned embodiments have been described with respect to the two parallel elements, the present invention can also be applied in a similar way to semiconductor devices having three or more transistor elements connected in parallel with each other. An application of the present invention can be made while increasing the current rating by increasing the number of parallel elements on the high-speed side or the low-speed side (providing, for example, one MOS element and two IGBT elements) according to a design concept.

The first and second transistor elements 1 and 4 are not limited to elements formed of silicon. Elements may be formed of a wide-bandgap semiconductor having a bandgap larger than that of silicon may suffice. The wide-bandgap semiconductor is, for example, silicon carbide, a gallium nitride based material or diamond. Power semiconductor elements formed of such a wide-bandgap semiconductor have a high withstand voltage and a high allowable current density and can therefore be made smaller in size. If a semiconductor module is formed by incorporating the elements made smaller in size, the semiconductor module can also be made smaller in size. Also, because the heat resistance of the elements is high, heat radiating fins of a heat sink for the semiconductor module can be reduced in size and a water cooling portion can be replaced with an air cooling portion, thereby enabling the semiconductor module to be further reduced in size. Also, because the elements have a low power loss and high efficiency, the semiconductor module can be improved in efficiency. It is desirable that both the first and second transistor elements 1 and 4 be formed of a wide-bandgap semiconductor. However, only one of the first and second transistor elements 1 and 4 may be formed of a wide-bandgap semiconductor. The advantages described in the embodiments can also be obtained in such a case.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2015-165964, filed on Aug. 25, 2015 including specification, claims, drawings and summary, on which the Convention priority of the present application is based, is incorporated herein by reference in its entirety.

1. A transistor element comprising:
a first semiconductor substrate on which a first transistor cell region is formed;
a first gate electrode pad formed on the first semiconductor substrate and connected to a gate in the first transistor cell region;
a relay electrode pad formed on the first semiconductor substrate; and
a gate resistance formed on the first semiconductor substrate and connected between the first gate electrode pad and the relay electrode pad.

2. The transistor element of claim 1, wherein the gate resistance is formed by ion implanting an impurity in non-doped polysilicon.

3. The transistor element of claim 1, wherein the gate resistance is formed by using doped polysilicon.

4. The transistor element of claim 1, wherein the gate resistance includes a plurality of resistances separated from each other and metal wires connecting the plurality of resistances to one another.

5. The transistor element of claim 1, wherein the gate resistor is formed by using a metal wire.

6. The transistor element of claim 5, wherein the gate resistance includes a plurality of metal wires connected in parallel with each other.

7. The transistor element of claim 1, further comprising an insulating film formed on the first transistor cell region,
wherein the relay electrode pad and the gate resistance are disposed on the insulating film.

8. The transistor element of claim 1, wherein the relay electrode pad includes a plurality of electrodes connected in series with each other, and
a plurality of resistances are connected between the plurality of electrodes respectively.

9. The transistor element of claim 1, wherein the relay electrode pad and the gate resistance are disposed in a region other than the first transistor cell region.

10. The transistor element of claim 1, further comprising a diode formed on the first semiconductor substrate and connected between the first gate electrode pad and the relay electrode pad.

11. The transistor element of claim 10, wherein the diode is connected in parallel with the gate resistance.

12. The transistor element of claim 10, wherein the diode is connected in series with the gate resistance.

13. The transistor element of claim 10, wherein the gate resistance includes first and second gate resistances connected in parallel with each other, and
the diode includes first and second diodes in a reverse parallel connection with each other and connected in series with the first and second gate resistances respectively.

14. A semiconductor device comprising:
a first transistor element which is the transistor element of claim 1;
a second transistor element being separate from the first transistor element; and
a wire,
wherein the second transistor element includes a second semiconductor substrate on which a second transistor cell region is formed, and a second gate electrode pad formed on the second semiconductor substrate and connected to a gate in the second transistor cell region, and
the wire connects the relay electrode pad to the second gate electrode pad.

15. The semiconductor device according to claim 14, wherein the second transistor element differs in characteristics from the first transistor element.
